(19) United States
(12) Patent Application Publication
(10) Pub. No.: US 2024/0416390 A1
(43) Pub. Date: Dec. 19, 2024

(54) SUBSTRATE PROCESSING APPARATUS

(71) Applicant: EBARA CORPORATION, Tokyo (JP)

(72) Inventors: Naoki TOYOMURA, Tokyo (JP); Junji KUNISAWA, Tokyo (JP); Mitsuru MIYAZAKI, Tokyo (JP)

(21) Appl. No.: 18/740,592

(22) Filed: Jun. 12, 2024

(30) Foreign Application Priority Data
Jun. 14, 2023 (JP) 2023-097706

(51) Int. Cl. B08B 3/02; B08B 5/00; H01L 21/67

(52) U.S. Cl. CPC B08B 3/02; B08B 5/00; B08B 2203/0205; B08B 2203/0247; H01L 21/67051

(57) ABSTRACT

The present disclosure provides a substrate processing apparatus capable of adjusting a flow rate of a liquid to be ejected from a nozzle. The substrate processing apparatus according to the present disclosure is a substrate processing apparatus including a nozzle configured to supply a liquid to a substrate, and a liquid supplier configured to supply the liquid to the nozzle, in which the liquid supplier includes a supply pipe which is configured to cause a liquid supply source and the nozzle to be in fluid communication and which has a first pipe constituting a first flow channel from a splitting point to a joining point located downstream of the splitting point and a second pipe constituting a second flow channel from the splitting point to the joining point, a first valve attached to the first pipe, a second valve attached to the second pipe, and a fluid resistance element attached to the second pipe and configured to set a pressure loss of the liquid flowing through the second pipe to be larger than a pressure loss of the liquid flowing through the first pipe.

### CROSS-REFERENCE TO RELATED APPLICATION

This application is based upon and claims benefits of priorities from Japanese Patent Application No. 2023-097706 filed on Jun. 14, 2023, the entire contents of which are incorporated herein by reference.

### TECHNICAL FIELD

The present invention relates to a substrate processing apparatus.

### BACKGROUND ART

In a semiconductor manufacturing process, a front surface of a substrate is polished by a CMP (Chemical Mechanical Polishing) apparatus. The polished substrate is cleaned to remove residues such as a polishing liquid and polishing chips remaining on the front surface and thereafter dried to be passed to a next process. Therefore, in the semiconductor manufacturing process, a substrate processing apparatus having a function of cleaning the substrate and a substrate processing apparatus having a function of drying the substrate are used.

For example, a substrate processing apparatus having a function of drying a substrate is disclosed in PTL 1. A substrate processing apparatus 1 disclosed in PTL 1 includes, as illustrated in FIG. 2 of PTL 1, a substrate holder 10 configured to hold and rotate a substrate W, a liquid nozzle 20, and a first rear surface nozzle 71. The liquid nozzle 20 is located above the substrate W held by the substrate holder 10. Then, the liquid nozzle 20 is configured to eject a liquid from upper to lower to supply the liquid to a front surface 2 of the substrate W. The first rear surface nozzle 71 is located below the substrate W held by the substrate holder 10. The first rear surface nozzle 71 is configured to eject the liquid from lower to upper to supply the liquid to a rear surface 3 of the substrate W.

In the substrate processing apparatus 1 of PTL 1, when the substrate holder 10 rotates the substrate W, the liquid on the substrate W is removed. In the substrate processing apparatus 1, before the liquid on the substrate W is removed, the liquid nozzle 20 and the first rear surface nozzle 71 supply the liquid to the substrate W. With this configuration, before the substrate W is dried, a uniform liquid film covering the substrate W is formed. By forming the uniform liquid film covering the substrate W before the drying, the substrate processing apparatus 1 avoids formation of watermarks on the substrate W during the drying.

The substrate processing apparatus 1 of PTL 1 further includes, as illustrated in FIG. 2 of PTL 1, a processing chamber 7, and a ventilation mechanism 8 arranged above the substrate holder 10. Then, the ventilation mechanism 8 includes a fan 8A, and a filter 8B configured to remove particles or dust in air sent from the fan 8A. The ventilation mechanism 8 is configured to feed clean air into the processing chamber 7. Therefore, a down flow of the clean air is formed in the processing chamber 7. By forming such a down flow of the air, the ventilation mechanism 8 can generate an orderly air flow on the front surface 2 and the rear surface 3 of the substrate W, and avoid adhesion of a substrate contaminant due to disturbance of the air flow.

In addition, a substrate processing apparatus having a function of cleaning a substrate is disclosed in PTL 2. The substrate processing apparatus of PTL 2 includes, as illustrated in FIG. 1 of PTL 2, a substrate holder 16 configured to hold a substrate W, a first cleaning liquid supply nozzle 26, and a first rear surface nozzle 40. The first cleaning liquid supply nozzle 26 is configured to eject a cleaning liquid from upper to lower and supply the cleaning liquid to a top surface of the substrate W. On the other hand, the first rear surface nozzle 40 is configured to eject the cleaning liquid from lower to upper and supply the cleaning liquid to a bottom surface of the substrate W. In the substrate processing apparatus of PTL 2, by the first cleaning liquid supply nozzle 26 and the first rear surface nozzle 40 supplying the cleaning liquid to the substrate W, both the front surface and the rear surface of the substrate W are cleaned.

Furthermore, a substrate processing apparatus having a function of cleaning a substrate is disclosed in PTL 3. A substrate processing apparatus 1 of PTL 3 includes, as illustrated in FIG. 1 of PTL 3, a substrate holding and rotation mechanism 20 configured to hold a substrate W, a nozzle 11, and a nozzle 15. The nozzle 11 is configured to eject a substrate cleaning liquid from upper to lower to supply the substrate cleaning liquid to the front surface of the substrate W. On the other hand, the nozzle 15 is configured to eject the substrate cleaning liquid from lower to upper to supply the substrate cleaning liquid to a rear surface of the substrate W. In the substrate processing apparatus of PTL 3, by the nozzle 11 and the nozzle 15 supplying the substrate cleaning liquid to the substrate W, both the front surface and the rear surface of the substrate W are cleaned.

### CITATION LIST

### Patent Literature

PTL 1: International Publication No. WO 2021/251050
PTL 2: Japanese Patent Laid-Open No. 2004-235216
PTL 3: Japanese Patent Laid-Open No. 2007-523463

### SUMMARY OF INVENTION

### Technical Problem

In a substrate processing apparatus, in a case where a liquid is not ejected from a nozzle for a long period of time, bacteria may glow in the liquid in a pipe or the like, and the liquid in the pipe may degrade. Therefore, in the substrate processing apparatus, an operation of ejecting the liquid in the pipe from the nozzle may be performed in advance before the liquid is supplied from the nozzle to a substrate. This operation is referred to as dummy dispense. In the substrate processing apparatus, when the dummy dispense is performed, an old liquid accumulated in the pipe is replaced with a new liquid. As a result, the new liquid is supplied to the substrate from the nozzle.

In a case where the first rear surface nozzle 71 in the substrate processing apparatus of PTL 1 performs the dummy dispense by ejecting the liquid at the same flow rate as that of the liquid supplied to the substrate W, a momentum of the ejected liquid may be too strong, and the ejected liquid may hit the filter 8B arranged above the first rear surface nozzle 71. In a case where the ejected liquid hits the filter 8B, the filter 8B gets wet to cause clogging. As a result, the ventilation mechanism 8 may cause malfunction. Therefore, at the time of the dummy dispense, the flow rate of the liquid ejected from the first rear surface nozzle 71 is demanded to be adjusted so that the liquid is ejected from the first rear surface nozzle 71 at a flow rate lower than that of a case where the liquid is supplied to the substrate W.

Furthermore, since the first rear surface nozzle 40 of PTL 2 and the nozzle 15 of PTL 3 eject the liquid upwards, in a case where the filter is arranged above these nozzles, a similar issue may occur.

In addition, at the time of the dummy dispense, from a perspective of saving the liquid to be used, not too much liquid is demanded to be ejected from the nozzle.

In view of the above, an aspect of the present disclosure is aimed at providing a substrate processing apparatus capable of adjusting a flow rate of a liquid ejected from a nozzle.

### Solution to Problem

A substrate processing apparatus according to an embodiment is a substrate processing apparatus including a nozzle configured to supply a liquid to a substrate, and a liquid supplier configured to supply the liquid to the nozzle, in which the liquid supplier includes a supply pipe which is configured to cause a liquid supply source and the nozzle to be in fluid communication and which has a first pipe constituting a first flow channel from a splitting point to a joining point located downstream of the splitting point and a second pipe constituting a second flow channel from the splitting point to the joining point, a first valve attached to the first pipe, a second valve attached to the second pipe, and a fluid resistance element attached to the second pipe and configured to set a pressure loss of the liquid flowing through the second pipe to be larger than a pressure loss of the liquid flowing through the first pipe.

### BRIEF DESCRIPTION OF DRAWINGS

FIG. 1 is a front view schematically illustrating a substrate processing apparatus according to an embodiment of the present disclosure;

FIG. 2 is a fluid circuit diagram illustrating a flow channel configuration of a liquid supplier illustrated in FIG. 1;

FIG. 3 is a fluid circuit diagram illustrating a flow channel configuration of a liquid supplier different from the liquid supplier illustrated in FIG. 2; and

FIG. 4 is a fluid circuit diagram illustrating a flow channel configuration of a liquid supplier different from the liquid supplier illustrated in FIGS. 2 and 3.

### DESCRIPTION OF EMBODIMENTS

Hereinafter, embodiments of the present invention will be described with reference to the drawings. In the drawings described below, the same or equivalent component is denoted by the same reference sign, and a duplicated description will not be repeated.

### <Substrate Processing Apparatus 100>

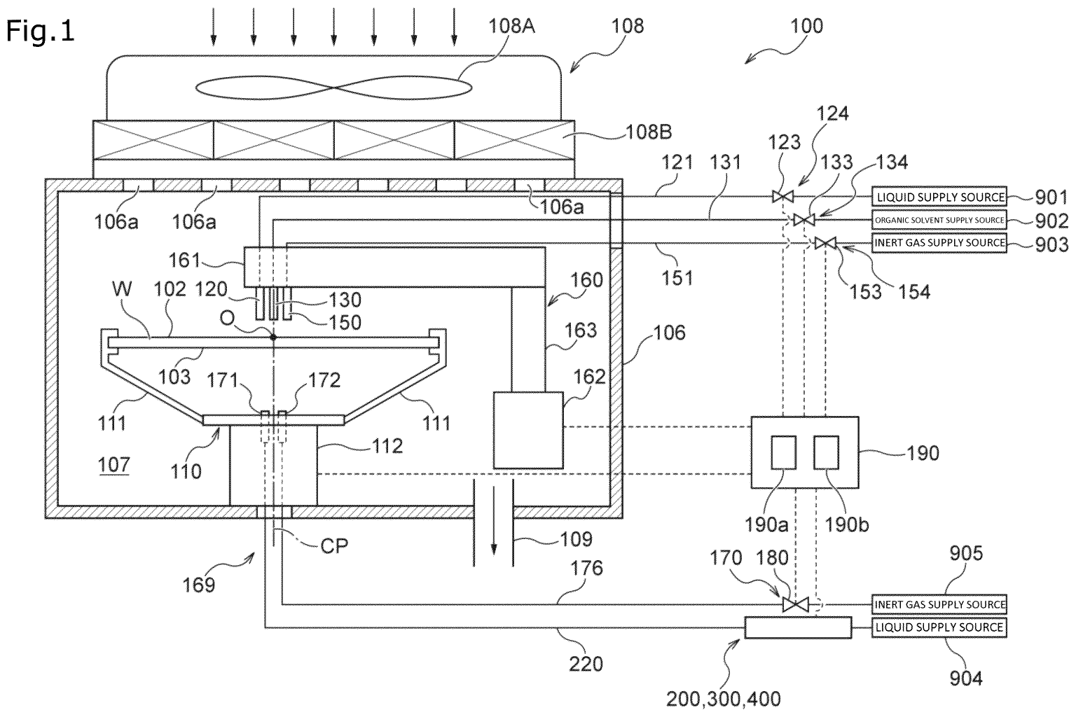

FIG. 1 is a front view schematically illustrating a substrate processing apparatus 100 according to an embodiment of the present disclosure. The substrate processing apparatus 100 is an apparatus configured to process a substrate W. With reference to FIG. 1, the substrate processing apparatus 100 includes a substrate holder 110 configured to hold and rotate the substrate W, and a controller 190. The substrate W to be processed by the substrate processing apparatus 100 is a substrate having been polished through chemical mechanical polishing (CMP), and is a substrate having been cleaned. Examples of a cleaning method include liquid cleaning (pure water, a chemical solution, and the like) and mechanical cleaning (sliding by a roll, a pencil, and the like), and further include cleaning in combination of the liquid cleaning and the mechanical cleaning, and the like. The substrate W includes a front surface 102 on which a flatting process has been performed.

The substrate holder 110 includes a plurality of chucks 111 configured to hold a rim of the substrate W, and a rotary motor 112 coupled to the plurality of chucks 111. The plurality of chucks 111 are configured to horizontally hold the substrate W. The rotary motor 112 is electrically connected to the controller 190. An operation of the rotary motor 112 is controlled by the controller 190. The substrate W held by the chucks 111 rotates about a shaft center CP of the substrate holder 110 by the rotary motor 112. The substrate holder 110 is configured to hold the substrate W in a state in which a center O of the substrate W matches the shaft center CP.

The substrate processing apparatus 100 also includes a liquid supply module 124 configured to supply a liquid to the substrate W, a solvent supply module 134 configured to supply an organic solvent to the substrate W, an inert gas supply module 154 configured to supply an inert gas to the substrate W, a first rear surface side supply module 169 configured to supply the liquid to the substrate W, and a second rear surface side supply module 170 configured to supply the inert gas to the substrate W.

The liquid supply module 124 includes a liquid nozzle 120 configured to supply the liquid to the substrate W, a liquid supply pipe 121 configured to supply the liquid to the liquid nozzle 120, and a liquid flow rate control valve 123. The liquid supply module 124 has a function of supplying the liquid from the liquid nozzle 120 to the substrate W. In more detail, the liquid supply pipe 121 is configured to cause the liquid nozzle 120 to be in fluid communication with a liquid supply source 901. The liquid nozzle 120 is arranged above the substrate W held by the substrate holder 110 and arranged so as to face downwards (facing the front surface 102 of the substrate W). With this configuration, the liquid is supplied from the liquid supply source 901 through the liquid supply pipe 121 to the liquid nozzle 120 and further supplied from the liquid nozzle 120 to the front surface 102 of the substrate W. It is noted that the liquid supplied by the liquid supply source 901 is de-ionized water (DIW) as an example.

The liquid flow rate control valve 123 is attached to the liquid supply pipe 121. The liquid flow rate control valve 123 is configured to open and close a flow channel of the liquid supply pipe 121, and has a function of adjusting a flow rate of the liquid (flow rate of the liquid supplied to the substrate W) flowing through the liquid supply pipe 121. The liquid flow rate control valve 123 is controlled by the controller 190.

The solvent supply module 134 includes a solvent nozzle 130 configured to supply the organic solvent to the substrate W, a supply pipe 131 configured to supply the organic solvent to the solvent nozzle 130, and a control valve 133. The solvent supply module 134 has a function of supplying the organic solvent from the solvent nozzle 130 to the substrate W. In more detail, the supply pipe 131 is configured to cause the solvent nozzle 130 to be in fluid communication with an organic solvent supply source 902. The solvent nozzle 130 is arranged above the substrate W held by the substrate holder 110 and arranged so as to face downwards (facing the front surface 102 of the substrate W). With this configuration, the organic solvent is supplied from the organic solvent supply source 902 through the supply pipe 131 to the solvent nozzle 130, and further supplied from the solvent nozzle 130 to the front surface 102 of the substrate W. It is noted that the organic solvent supplied by the organic solvent supply source 902 is a liquid or a gas as an example, and includes IPA (isopropyl alcohol) and a fluorine-based solvent containing alcohol.

The control valve 133 is attached to the supply pipe 131. The control valve 133 is configured to open and close a flow channel of the supply pipe 131, and has a function of adjusting a flow rate of the organic solvent (flow rate of the organic solvent supplied to the front surface 102 of the substrate W) flowing through the supply pipe 131. The control valve 133 is controlled by the controller 190.

The inert gas supply module 154 includes an inert gas nozzle 150 configured to supply the inert gas to the substrate W, an inert gas supply pipe 151 configured to supply the inert gas to the inert gas nozzle 150, and an inert gas flow rate control valve 153. The inert gas supply module 154 has a function of supplying the inert gas from the inert gas nozzle 150 to the substrate W. The inert gas supply pipe 151 is configured to causes the inert gas nozzle 150 to be in fluid communication with an inert gas supply source 903. The inert gas nozzle 150 is arranged above the substrate W held by the substrate holder 110 and arranged so as to face downwards (facing the front surface 102 of the substrate W). With this configuration, the inert gas is supplied from the inert gas supply source 903 through the inert gas supply pipe 151 to the inert gas nozzle 150, and further supplied from the inert gas nozzle 150 to the front surface 102 of the substrate W. It is noted that the inert gas supplied by the inert gas supply source 903 is nitrogen as an example.

The inert gas flow rate control valve 153 is attached to the inert gas supply pipe 151. The inert gas flow rate control valve 153 is configured to open and close a flow channel of the inert gas in the inert gas supply pipe 151, and has a function of adjusting a flow rate of the inert gas (flow rate of the inert gas supplied to the front surface 2 of the substrate W) flowing through the inert gas supply pipe 151. The inert gas flow rate control valve 153 is controlled by the controller 190.

The first rear surface side supply module 169 includes a first rear surface nozzle (nozzle) 171 configured to supply the liquid to the substrate W, and a liquid supplier 200. The first rear surface side supply module 169 has a function of supplying the liquid from the first rear surface nozzle 171 to the substrate W. The first rear surface nozzle 171 is located immediately below the substrate W held by the substrate holder 110 and configured to eject the liquid upwards. The liquid supplier 200 is configured to supply the liquid to the first rear surface nozzle 171. It is noted that a detailed configuration of the liquid supplier 200 will be described below.

The second rear surface side supply module 170 includes a second rear surface nozzle 172 configured to supply the inert gas to the substrate W, a second rear surface side supply pipe 176 configured to supply the inert gas to the second rear surface nozzle 172, and a second rear surface side flow rate control valve 180. The second rear surface side supply module 170 has a function of supplying the inert gas from the second rear surface nozzle 172 to the substrate W. In more detail, the second rear surface side supply pipe 176 is configured to cause the second rear surface nozzle 172 to be in fluid communication with an inert gas supply source 905. The second rear surface nozzle 172 is located immediately below the substrate W held by the substrate holder 110 and configured to eject the inert gas upwards. With this configuration, the inert gas is supplied from the inert gas supply source 905 through the second rear surface side supply pipe 176 to the second rear surface nozzle 172, and further supplied from the second rear surface nozzle 172 to a rear surface 103 of the substrate W. It is noted that the inert gas supplied by the inert gas supply source 905 is nitrogen as an example.

The second rear surface side flow rate control valve 180 is attached to the second rear surface side supply pipe 176. The second rear surface side flow rate control valve 180 is configured to open and close a flow channel of the inert gas in the second rear surface side supply pipe 176, and has a function of adjusting a flow rate of the inert gas (flow rate of the inert gas supplied to the rear surface 3 of the substrate W) flowing through the second rear surface side supply pipe 176. The second rear surface side flow rate control valve 180 is controlled by the controller 190.

The substrate processing apparatus 100 further includes a nozzle movement module 160 configured to move the liquid nozzle 120, the solvent nozzle 130, and the inert gas nozzle 150. The nozzle movement module 160 includes an arm 161 arranged above the substrate W held by the substrate holder 110, a swing motor 162 configured to cause the arm 161 to swing, and a pivot shaft 163 coupled to the swing motor 162. The arm 161 has a length longer than a radius of the substrate W. The liquid nozzle 120, the solvent nozzle 130, and the inert gas nozzle 150 are attached to a distal end of the arm 161. The pivot shaft 163 is connected to another end of the arm 161.

The swing motor 162 is electrically connected to the controller 190, and an operation of the swing motor 162 is controlled by the controller 190. By rotating the pivot shaft 163 by a predetermined degree, the swing motor 162 causes the arm 161 to swing in a plane parallel to the substrate W. In other words, with the swinging of the arm 161, the liquid nozzle 120, the solvent nozzle 130, and the inert gas nozzle 150 which are fixed to the arm 161 move in a radius direction of the substrate W. During the processing on the substrate W, the nozzle movement module 160 can move the liquid nozzle 120, the solvent nozzle 130, and the inert gas nozzle 150 together from a center of the substrate W towards the rim of the substrate W.

The controller 190 is configured to control the operations of the substrate holder 110, the liquid supply module 124, the solvent supply module 134, the inert gas supply module 154, the first rear surface side supply module 169, the second rear surface side supply module 170, and the nozzle movement module 160. The controller 190 includes a storage 190a storing a program, and an arithmetic device 190b configured to execute an arithmetic operation following instructions included in the program. The arithmetic device 190b includes a CPU (Central Processing Unit), a GPU (Graphics Processing Unit), and the like configured to perform the arithmetic operation following the instructions included in the program stored in the storage 190a. The storage 190a includes a main storage (for example, a random access memory) which can be accessed by the arithmetic device 190b, and an auxiliary storage storing data and a program (for example, a hard disk drive or a solid state drive). The program in the controller 190 includes a recipe for the substrate processing apparatus 100 to execute a processing method of the substrate W.

The substrate processing apparatus 100 further includes a partition wall 106, and a ventilator 108 arranged above the substrate holder 110 and the substrate W. An internal space defined by the partition wall 106 constitutes a processing chamber 107. The substrate holder 110, the liquid nozzle 120, the solvent nozzle 130, the inert gas nozzle 150, the nozzle movement module 160, the first rear surface nozzle 171, and the second rear surface nozzle 172 are arranged inside the processing chamber 107. A door which is not illustrated in the drawing is provided to the partition wall 106. The substrate W is carried into the processing chamber 107 through this door and taken out from the processing chamber 107. Clean air intakes 106a are formed at a top of the partition wall 106. An exhaust duct 109 is formed at a bottom of the partition wall 106. The ventilator 108 is installed on an upper surface of the partition wall 106. The ventilator 108 includes a fan 108A and a filter 108B. The filter 108B is located immediately above the substrate holder 110 and the substrate W held by the substrate holder 110, and has a function of removing particles and dust in the air blown from the fan 108A. The ventilator 108 feeds the clean air into the processing chamber 107 through the clean air intakes 106a, and causes a gas inside the processing chamber 107 to be discharged from the exhaust duct 109. With this configuration, a down flow of the clean air is formed inside the processing chamber 107. In other words, the ventilator 108 is configured to supply the down flow of the air to the substrate W. With the formation of such a down flow of the air, an orderly air flow is generated on the front surface 102 and the rear surface 103 of the substrate W, and adherence of a substrate contaminant due to disturbance of the air flow is suppressed.

### <Liquid Supplier 200>

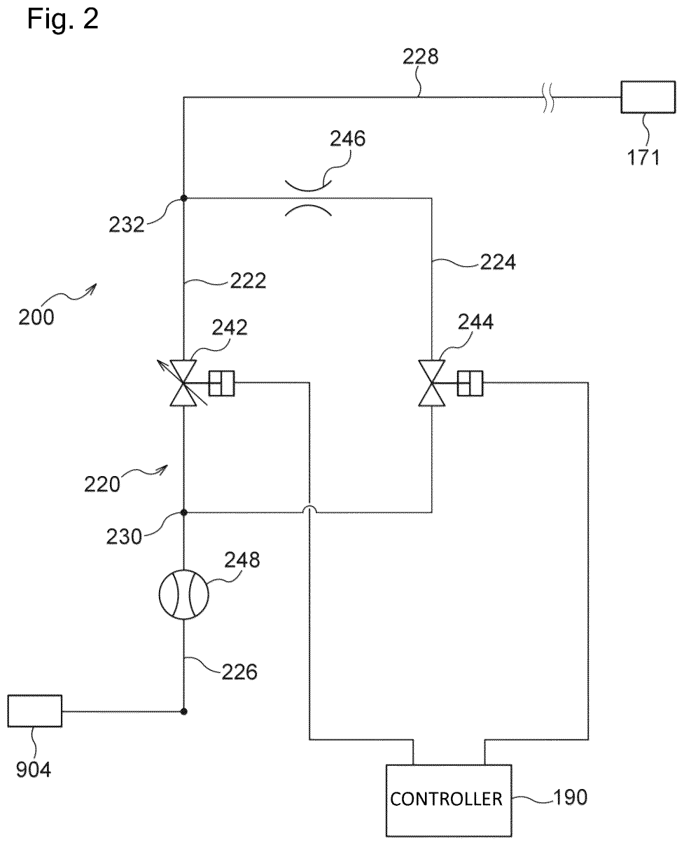

FIG. 2 is a fluid circuit diagram illustrating a flow channel configuration of the liquid supplier 200 illustrated in FIG. 1. With reference to FIG. 2, a detailed configuration of the liquid supplier 200 will be described. With reference to FIG. 2, the liquid supplier 200 includes a supply pipe 220, a first valve 242, a second valve 244, and a fluid resistance element 246.

The supply pipe 220 is configured to cause the first rear surface nozzle 171 to be in fluid communication with a liquid supply source 904. In more detail, the supply pipe 220 includes a first pipe 222, a second pipe 224, an upstream pipe 226, and a downstream pipe 228. The first pipe 222 constitutes a first flow channel from a splitting point 230 to a joining point 232 located downstream of the splitting point 230. The second pipe 224 constitutes a second flow channel different from the first flow channel from the splitting point 230 to the joining point 232. The upstream pipe 226 constitutes a flow channel from the liquid supply source 904 to the splitting point 230. The downstream pipe 228 constitutes a flow channel from the joining point 232 to the first rear surface nozzle 171. Since the supply pipe 220 has such a configuration, the liquid supplied from the liquid supply source 904 can flow through one of the first pipe 222 and the second pipe 224 to be supplied to the first rear surface nozzle 171. In other words, the liquid supplier 200 can supply the liquid to the first rear surface nozzle 171 via the first pipe 222 or via the second pipe 224. It is noted that the liquid supplied by the liquid supply source 904 is de-ionized water (DIW) as an example. However, in another embodiment according to the present disclosure, the liquid supplied by the liquid supply source 904 may be a liquid other than de-ionized water.

The fluid resistance element 246 is attached to a downstream side relative to the second valve 244 of the second pipe 224. The fluid resistance element 246 is an orifice as an example, and has a function of setting a pressure loss of the liquid flowing through the second pipe 224 to be larger than a pressure loss of the liquid flowing through the first pipe 222. Put simply, in the liquid supplier 200, the pressure loss of the liquid flowing through the second pipe 224 is larger than the pressure loss of the liquid flowing through the first pipe 222. As a result, the flow rate of the liquid ejected from the first rear surface nozzle 171 via the second pipe 224 becomes lower than the flow rate of the liquid ejected from the first rear surface nozzle 171 via the first pipe 222. Put simply, in the substrate processing apparatus 100, the flow rate of the liquid ejected from the first rear surface nozzle 171 varies depending on the pipes (the first pipe 222 and the second pipe 224) to be used. In other words, the substrate processing apparatus 100 can adjust the flow rate of the liquid ejected from the first rear surface nozzle 171. It is noted that in another embodiment according to the present disclosure, the fluid resistance element 246 may be a component other than the orifice which is configured to apply a pressure loss to the liquid flowing through the second pipe 224. For example, the fluid resistance element 246 may include a throttle configured to decrease a pipe diameter, bending, or the like.

As an example, the fluid resistance element 246 may be configured to apply the pressure loss to the liquid flowing through the second pipe 224 such that the flow rate of the liquid flowing through the second pipe 224 becomes 80 ml/min, 100 ml/min, 200 ml/min, 240 ml/min, 270 ml/min, or 50 to 300 ml/min.

At the time of the dummy dispense of the first rear surface nozzle 171, in a case where the liquid ejected from the first rear surface nozzle 171 hits the filter 108B, the filter 108B gets wet to cause clogging, and the ventilator 108 may cause malfunction (see FIG. 1). In contrast, in the substrate processing apparatus 100, the fluid resistance element 246 is configured to apply the pressure loss to the liquid flowing through the second pipe 224 to obtain such a flow rate that the liquid ejected from the first rear surface nozzle 171 does not hit the filter 108B. Therefore, the liquid ejected from the first rear surface nozzle 171 via the second pipe 224 does not hit the filter 108B. As a result, in the substrate processing apparatus 100, the filter 108B does not get wet to cause clogging, and the malfunction of the ventilator 108 due to this clogging does not occur.

Furthermore, even if the second valve 244 is not working and is put into a state of being unable to be closed, the fluid resistance element 246 applies the pressure loss to the liquid flowing through the second pipe 224. With this configuration, the fluid resistance element 246 can reliably set the flow rate of the liquid flowing through the second pipe 224 to be supplied to the first rear surface nozzle 171 to be lower than the flow rate of the liquid flowing through the first pipe 222 to be supplied to the first rear surface nozzle 171. Put simply, in the substrate processing apparatus 100, even when the second valve 244 is not working, such a situation is reliably avoided where the liquid ejected from the first rear surface nozzle 171 via the second pipe 224 hits the filter 108B.

The first valve 242 is attached to the first pipe 222 and controlled by the controller 190. Then, the first valve 242 is configured to open and close the first flow channel of the first pipe 222. With this configuration, when the first valve 242 is opened, the liquid is supplied to the first rear surface nozzle 171 via the first pipe 222. On the other hand, when the first valve 242 is closed, the liquid supplied to the first rear surface nozzle 171 via the first pipe 222 stops.

The first valve 242 is a needle valve as an example, and is configured in a manner that a valve opening degree is adjustable when opened. In a case where the first valve 242 has such a configuration, an operator can adjust the valve opening degree of the first valve 242 when opened. The flow rate of the liquid flowing through the first pipe 222 depends on the valve opening degree of the first valve 242 when opened. Therefore, by adjusting the valve opening degree of the first valve 242 when opened, the operator can adjust the flow rate of the liquid flowing through the first pipe 222. That is, the substrate processing apparatus 100 can set the flow rate of the liquid ejected from the first rear surface nozzle 171 via the first pipe 222 to the flow rate set by the operator. It is noted that as an example, the valve opening degree of the first valve 242 when opened may be adjusted such that the flow rate of the liquid flowing through the first pipe 222 becomes 1000 ml/min.

In this manner, in the liquid supplier 200, since the operator adjusts the valve opening degree of the first valve 242 when opened, the flow rate of the liquid supplied to the first rear surface nozzle 171 via the first pipe 222 can be changed. However, the operation of adjusting the valve opening degree to change the flow rate may become trouble of the operator. In contrast, the liquid supplier 200 can supply the liquid to the first rear surface nozzle 171 also via the second pipe 224 as described above. That is, the liquid supplier 200 can supply the liquid to the first rear surface nozzle 171 at different flow rates without adjusting the valve opening degree of the first valve 242 when opened by the operator.

The second valve 244 is attached to the second pipe 224 and controlled by the controller 190. Then, the second valve 244 is configured to open and close the second flow channel of the second pipe 224. With this configuration, when the second valve 244 is opened, the liquid is supplied to the first rear surface nozzle 171 via the second pipe 224. On the other hand, when the second valve 244 is closed, the liquid supplied to the first rear surface nozzle 171 via the second pipe 224 stops. It is noted that the second valve 244 is an on/off valve as an example. In the present disclosure, the on/off valve means a valve which can take only two-stage configurations including a configuration in which the valve opening degree becomes fully open and a configuration in which the valve opening degree becomes fully closed. It is noted that an example of a configuration in which the valve opening degree of the second valve when opened can be adjusted will be described below.

The liquid supplier 200 further includes a flowmeter 248 (see FIG. 2). The flowmeter 248 is attached to an upstream position relative to the splitting point 230 of the supply pipe 220. In other words, the flowmeter 248 is attached to the upstream pipe 226. The flowmeter 248 is an ultrasonic flowmeter as an example, and has a function of measuring the flow rate of the liquid flowing through the upstream pipe 226. With this configuration, the flowmeter 248 can measure the flow rate of the liquid ejected from the first rear surface nozzle 171.

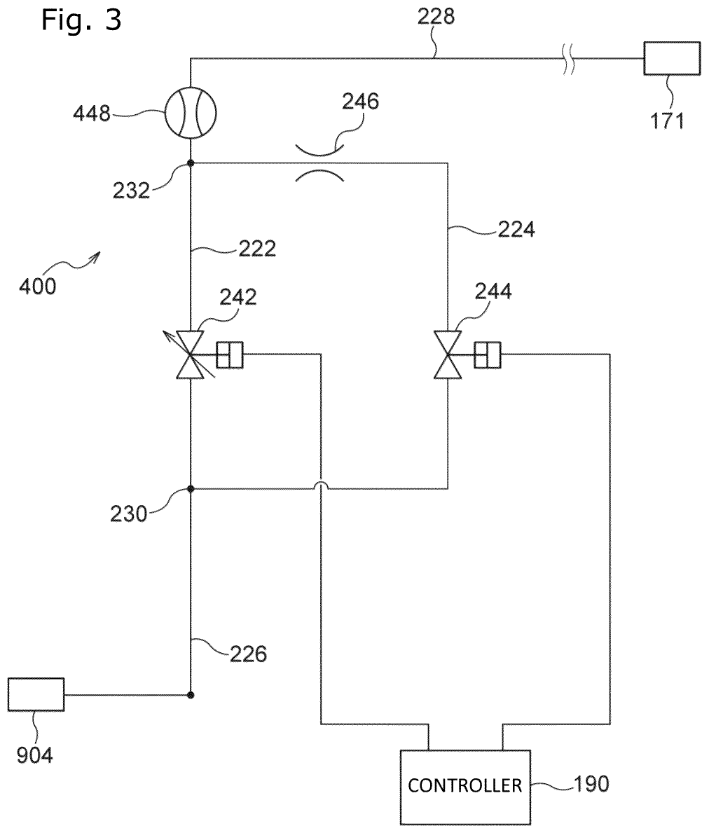

It is noted that the flowmeter may be attached to a position other than the upstream position relative to the splitting point 230 of the supply pipe 220 as long as the flow rate of the liquid ejected from the first rear surface nozzle 171 can be measured. For example, the flowmeter may be attached at a position illustrated in FIG. 3. FIG. 3 is a fluid circuit diagram illustrating a flow channel configuration of a liquid supplier 400 different from the liquid supplier 200. With reference to FIG. 3, a flowmeter 448 is attached to a downstream side relative to the joining point 232 of the supply pipe 220. In other words, a flowmeter 428 is attached to the downstream pipe 228. Even when the flowmeter 428 is attached to the above-described position, the flowmeter 428 can measure the flow rate of the liquid ejected from the first rear surface nozzle 171.

However, the flowmeter is preferably arranged upstream of the splitting point 230 like the flowmeter 248. A reason for this will be described below.

It is generally known that air bubbles are less likely to be generated in a more pressurized liquid as compared with an unpressurized liquid. In the liquid supplier 200 and the liquid supplier 400, an upstream position relative to the first valve 242 or the second valve 244 is not in fluid communication with the first rear surface nozzle 171 when the first valve 242 and the second valve 244 are closed, and is regularly applied with the pressure of the liquid supplied from the liquid supply source 904. On the other hand, a downstream side relative to the first valve 242 or the second valve 244 is in fluid communication with the first rear surface nozzle 171 even when the first valve 242 and the second valve 244 are closed. Therefore, the downstream side relative to the first valve 242 or the second valve 244 is not pressurized with the pressure of the liquid supplied from the liquid supply source 904. Based on these, air bubbles are less likely to be generated inside the supply pipe 220 located upstream of the first valve 242 or the second valve 244 as compared with inside the supply pipe 220 located downstream of the first valve 242 or the second valve 244.

In a case where air bubbles are contained in the liquid the flow rate of which is measured by the flowmeter, the flowmeter may not be able to appropriately measure the flow rate. Therefore, the flowmeter preferably measures the flow rate in a position where the liquid hardly containing air bubbles flows. That is, the flowmeter can more appropriately measure the flow rate when the flowmeter is arranged in the upstream position relative to the first valve 242 or the second valve 244 where air bubbles are less likely to be generated. Thus, the flowmeter 248 of the liquid supplier 200 can more appropriately measure the flow rate than the flowmeter 448 of the liquid supplier 400.

When the substrate holder 110 holds the substrate W, the controller 190 may control the liquid supplier 200 to supply the liquid to the first rear surface nozzle 171 via the first pipe 222 (see FIG. 2). In other words, when the substrate holder 110 holds the substrate W, the controller 190 may control the liquid supplier 200 so as to open the first valve 242 and close the second valve 244. On the other hand, when the substrate holder 110 does not hold the substrate W (upon dummy dispense), the controller 190 may control the liquid supplier 200 to supply the liquid to the first rear surface nozzle 171 via the second pipe 224. In other words, the controller 190 may control the liquid supplier 200 so as to close the first valve 242 and open the second valve 244 when the substrate holder 110 does not hold the substrate W.

When the controller 190 performs the above-described control, the first rear surface nozzle 171 can supply the liquid to the substrate W at a higher flow rate. On the other hand, the liquid supplier 200 can decrease the flow rate when the substrate holder 110 does not hold the substrate W (upon dummy dispense).

As described above, in a case where air bubbles are contained in the liquid the flow rate of which is measured by the flowmeter, the flowmeter may not be able to appropriately measure the flow rate. Air bubbles tend to remain in a portion extending in a horizontal direction of the pipe. Therefore, when the flowmeter is attached at the portion extending in the horizontal direction of the pipe, a defect may occur in which the flow rate may not be appropriately measured due to an influence from the remaining air bubbles. In contrast, in the liquid supplier 200, the flowmeter 248 is attached to a portion extending at an angle with respect to the horizontal direction of the supply pipe 220. Air bubbles hardly remain in such a portion. Put simply, the above-described defect hardly occurs in the liquid supplier 200.

### <Liquid Supplier 300>

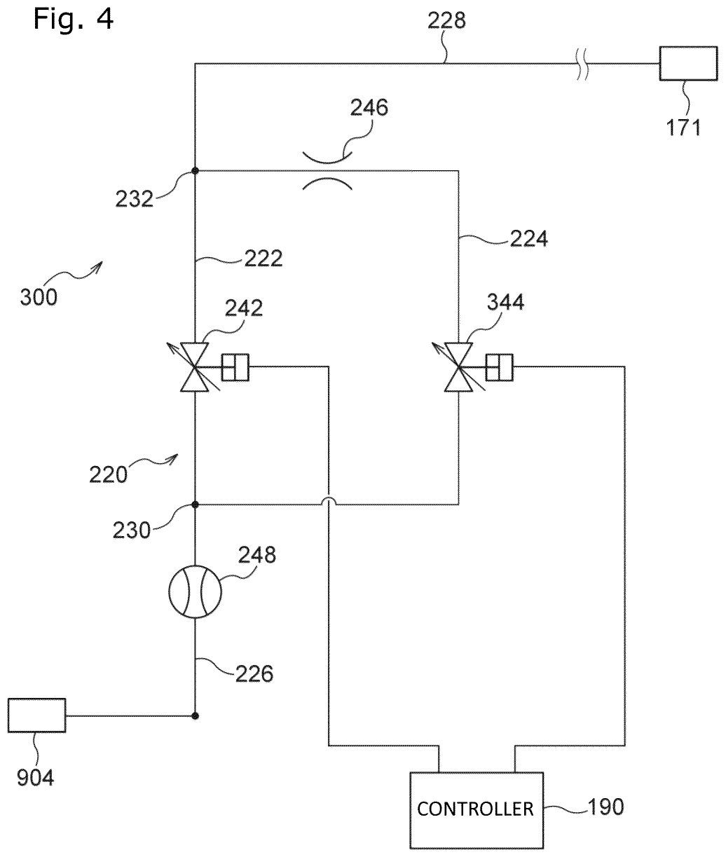

FIG. 4 is a fluid circuit diagram illustrating a flow channel configuration of a liquid supplier 300 different from the liquid supplier 200. The liquid supplier 300 can be used in the substrate processing apparatus 100 instead of the liquid supplier 200. The liquid supplier 300 partially has a configuration common to the liquid supplier 200. Hereinafter, a difference from the liquid supplier 200 will be mainly described with regard to the liquid supplier 300. The common configuration is denoted by the same reference sign in the drawing, and a description thereof will be omitted.

With reference to FIG. 4, the liquid supplier 300 includes the flowmeter 248 attached to the upstream pipe 226. Therefore, in a case where the first valve 242 is closed and the second valve 244 is opened, the flowmeter 248 can measure the flow rate of the liquid flowing through the second pipe 224.

In general, the flowmeter has a measurable range of the flow rate. In the liquid supplier 300, the flowmeter 248 is configured such that the flow rate of the liquid flowing through the second pipe 224 falls within the measurable range of the flowmeter 248. In other words, the flowmeter 248 is configured to be able to measure the flow rate of the liquid flowing through the second pipe 224. With this configuration, the liquid supplier 300 achieves the following effects.

If the flowmeter 248 is unable to measure the flow rate of the liquid flowing through the second pipe 224, it is difficult for the operator to find out the occurrence of the clogging in the second pipe 224. In contrast, in the liquid supplier 300, the flowmeter 248 can measure the flow rate of the liquid flowing through the second pipe 224. With this configuration, when the clogging occurs in the second pipe 224, a measured value of the flowmeter 248 approaches zero. As a result, the operator can find out the occurrence of the clogging in the second pipe 224.

With reference to FIG. 4 again, the liquid supplier 300 includes a second valve 344 instead of the second valve 244 included in the liquid supplier 200. The second valve 344 is attached to the second pipe 224 and controlled by the controller 190. Then, the second valve 344 is configured to open and close the second flow channel of the second pipe 224. The second valve 344 is a needle valve as an example. Unlike the second valve 244, the second valve 344 is configured in a manner that a valve opening degree is adjustable when opened. Therefore, the operator can adjust the valve opening degree of the second valve 344 when opened. The flow rate of the liquid flowing through the second pipe 224 depends on the valve opening degree of the second valve 344 when opened. Therefore, the operator can adjust the flow rate of the liquid flowing through the second valve 344 by adjusting the valve opening degree of the second valve 344 when opened. That is, the liquid supplier 300 can set the flow rate of the liquid ejected from the first rear surface nozzle 171 via the second pipe 224 to a flow rate set by the operator.

In a case where the pressure of the liquid supplied by the liquid supply source 904 varies since a specification of the liquid supply source 904 is changed, the flow rate of the liquid flowing through the second pipe 224 varies. In this case, the flow rate of the liquid flowing through the second pipe 224 may fall out of a range of the flow rate which can be measured by the flowmeter 248. However, in the liquid supplier 300, as described above, the operator can adjust the flow rate of the liquid flowing through the second valve 344 by adjusting the valve opening degree of the second valve 344 when opened. Therefore, even when the pressure of the liquid supplied by the liquid supply source 904 is changed, the operator adjusts the flow rate of the liquid flowing through the second pipe 224 to avoid a situation where the flow rate of the liquid flowing through the second pipe 224 falls out of the range of the flow rate which can be measured by the flowmeter 248.

It is noted that as described above, the liquid supplier 400 of FIG. 3 includes the second valve 244. The second valve 244 is an on/off valve as an example. However, in another embodiment according to the present disclosure, the liquid supplier 400 may include the second valve 344 in which the valve opening degree when opened can be adjusted instead of the second valve 244.

### SUPPLEMENTS

Some or all of the above-described embodiments may also be described in the following supplements, but are not limited to configurations described below.

### Supplement 1

A substrate processing apparatus according to supplement 1 is a substrate processing apparatus including a nozzle configured to supply a liquid to a substrate, and a liquid supplier configured to supply the liquid to the nozzle, in which the liquid supplier includes a supply pipe which is configured to cause a liquid supply source and the nozzle to be in fluid communication and which has a first pipe constituting a first flow channel from a splitting point to a joining point located downstream of the splitting point and a second pipe constituting a second flow channel from the splitting point to the joining point, a first valve attached to the first pipe, a second valve attached to the second pipe, and a fluid resistance element attached to the second pipe and configured to set a pressure loss of the liquid flowing through the second pipe to be larger than a pressure loss of the liquid flowing through the first pipe.

The substrate processing apparatus according to supplement 1 can supply the liquid to the nozzle via the first pipe or via the second pipe. Put simply, this substrate processing apparatus can adjust a flow rate of the liquid ejected from the nozzle. Furthermore, even if the second valve is not working and is put into a state of being unable to be closed, the fluid resistance element applies the pressure loss to the liquid flowing through the second pipe. With this configuration, the fluid resistance element can reliably set the flow rate of the liquid flowing through the second pipe to be supplied to the nozzle to be lower than the flow rate of the liquid flowing through the first pipe to be supplied to the nozzle.

### Supplement 2

A substrate processing apparatus according to supplement 2 is the substrate processing apparatus according to supplement 1, in which the fluid resistance element is an orifice.

In the substrate processing apparatus according to supplement 2, the orifice increases the pressure loss of the liquid flowing through the second pipe.

### Supplement 3

A substrate processing apparatus according to supplement 3 is the substrate processing apparatus according to supplement 1 or 2, further including a ventilator arranged above the substrate and configured to provide a down flow of air to the substrate.

In accordance with the substrate processing apparatus according to supplement 3, since the ventilator forms the down flow of air, an orderly air flow is generated on a front surface and a rear surface of the substrate. As a result, this substrate processing apparatus can avoid adhesion of a substrate contaminant to the substrate due to disturbance of the air flow.

### Supplement 4

A substrate processing apparatus according to supplement 4 is the substrate processing apparatus according to supplement 3, in which the ventilator has a filter located immediately above the substrate, the nozzle is located immediately below the substrate and configured to eject the liquid upwards, and the fluid resistance element is configured to apply the pressure loss to the liquid flowing through the second pipe to obtain such a flow rate that the liquid ejected from the nozzle does not hit the filter.

In a case where the liquid hits the filter, the filter gets wet to cause clogging, and the ventilator may cause malfunction. In contrast, in the substrate processing apparatus according to supplement 4, the liquid ejected from the nozzle via the second pipe does not hit the filter. Therefore, in this substrate processing apparatus, the filter does not get wet to cause clogging, and the malfunction of the ventilator due to this clogging does not occur.

### Supplement 5

A substrate processing apparatus according to supplement 5 is the substrate processing apparatus according to supplement 1 or 2, including a substrate holder configured to hold the substrate and a controller, in which the nozzle is configured to be able to supply the liquid to the substrate held by the substrate holder, the controller controls the liquid supplier so as to supply the liquid to the nozzle via the first pipe when the substrate holder holds the substrate, and the controller controls the liquid supplier so as to supply the liquid to the nozzle via the second pipe when the substrate holder does not hold the substrate.

The substrate processing apparatus according to supplement 5 can decrease the flow rate when the substrate holder does not hold the substrate (upon dummy dispense).

### Supplement 6

A substrate processing apparatus according to supplement 6 is the substrate processing apparatus according to supplement 1 or 2, in which the first valve is configured in a manner that a valve opening degree is adjustable when opened.

The substrate processing apparatus according to supplement 6 can set the flow rate of the liquid ejected from the nozzle via the first pipe to a flow rate set by an operator.

### Supplement 7

A substrate processing apparatus according to supplement 7 is the substrate processing apparatus according to supplement 1 or 2, in which the second valve is configured in a manner that a valve opening degree is adjustable when opened.

The substrate processing apparatus according to supplement 7 can set the flow rate of the liquid ejected from the nozzle via the second pipe to a flow rate set by an operator.

### Supplement 8

A substrate processing apparatus according to supplement 8 is the substrate processing apparatus according to supplement 1 or 2, in which the liquid supplier includes a flowmeter configured to measure a flow rate of the liquid supplied to the nozzle by the liquid supplier.

The substrate processing apparatus according to supplement 8 can measure the flow rate of the liquid ejected from the nozzle by using the flowmeter.

### Supplement 9

A substrate processing apparatus according to supplement 9 is the substrate processing apparatus according to supplement 8, in which the flowmeter is configured to be able to measure a flow rate of the liquid flowing through the second pipe.

In a case where the flowmeter is unable to measure the flow rate of the liquid flowing through the second pipe, it is difficult for the operator to find out occurrence of clogging in the second pipe. In contrast, in the substrate processing apparatus according to supplement 9, the flowmeter is configured to be able to measure the flow rate of the liquid flowing through the second pipe. With this configuration, in this substrate processing apparatus, the operator can find out the occurrence of the clogging in the second pipe.

### Supplement 10

A substrate processing apparatus according to supplement 10 is the substrate processing apparatus according to supplement 8, in which the flowmeter is arranged upstream of the splitting point.

In the substrate processing apparatus according to supplement 10, the flowmeter can measure the flow rate at a position where the liquid hardly containing air bubbles flows, and can more appropriately measure the flow rate as compared with a case where the flowmeter is arranged downstream of the first valve or the second valve.

### Supplement 11

A substrate processing apparatus according to supplement 11 is the substrate processing apparatus according to supplement 8, in which the flowmeter is attached to a portion extending at an angle with respect to a horizontal direction of the supply pipe.

In the substrate processing apparatus according to supplement 11, the flowmeter is attached to the portion extending at an angle with respect to the horizontal direction of the supply pipe. Air bubbles hardly remain in such a portion. Put simply, in this substrate processing apparatus, a defect of the flowmeter due to the air bubbles hardly occurs.

### REFERENCE SIGNS LIST

100: substrate processing apparatus
108: ventilator
108B: filter
110: substrate holder
171: first rear surface nozzle (nozzle)
190: controller
200, 300, 400: liquid supplier
220: supply pipe
222: first pipe
224: second pipe
230: splitting point
232: joining point
242: first valve
244, 344: second valve
246: fluid resistance element (orifice)
248, 448: flowmeter
904: liquid supply source
W: substrate

What is claimed is:

1. A substrate processing apparatus comprising:
a nozzle configured to supply a liquid to a substrate; and
a liquid supplier configured to supply the liquid to the nozzle, wherein
the liquid supplier includes
a supply pipe which is configured to cause a liquid supply source and the nozzle to be in fluid communication and which has a first pipe constituting a first flow channel from a splitting point to a joining point located downstream of the splitting point and a second pipe constituting a second flow channel from the splitting point to the joining point,
a first valve attached to the first pipe,
a second valve attached to the second pipe, and
a fluid resistance element attached to the second pipe and configured to set a pressure loss of the liquid flowing through the second pipe to be larger than a pressure loss of the liquid flowing through the first pipe.

2. The substrate processing apparatus according to claim 1, wherein
the fluid resistance element is an orifice.

3. The substrate processing apparatus according to claim 1, further comprising:
a ventilator arranged above the substrate and configured to provide a down flow of air to the substrate.

4. The substrate processing apparatus according to claim 3, wherein
the ventilator has a filter located immediately above the substrate,
the nozzle is located immediately below the substrate and configured to eject the liquid upwards, and
the fluid resistance element is configured to apply the pressure loss to the liquid flowing through the second pipe to obtain such a flow rate that the liquid ejected from the nozzle does not hit the filter.

5. The substrate processing apparatus according to claim 1, comprising:
a substrate holder configured to hold the substrate; and
a controller, wherein
the nozzle is configured to supply the liquid to the substrate held by the substrate holder,
the controller controls the liquid supplier so as to supply the liquid to the nozzle via the first pipe when the substrate holder holds the substrate, and
the controller controls the liquid supplier so as to supply the liquid to the nozzle via the second pipe when the substrate holder does not hold the substrate.

6. The substrate processing apparatus according to claim 1, wherein
the first valve is configured in a manner that a valve opening degree is adjustable when opened.

7. The substrate processing apparatus according to claim 1, wherein
the second valve is configured in a manner that a valve opening degree is adjustable when opened.

8. The substrate processing apparatus according to claim 1, wherein
the liquid supplier includes a flowmeter configured to measure a flow rate of the liquid supplied to the nozzle by the liquid supplier.

9. The substrate processing apparatus according to claim 8, wherein
the flowmeter is configured to be able to measure a flow rate of the liquid flowing through the second pipe.

10. The substrate processing apparatus according to claim 8, wherein
the flowmeter is arranged upstream of the splitting point.

11. The substrate processing apparatus according to claim 8, wherein
the flowmeter is attached to a portion extending at an angle with respect to a horizontal direction of the supply pipe.
